(19) United States
(12) Patent Application Publication
(10) Pub. No.: US 2026/0196956 A1
(43) Pub. Date: Jul. 9, 2026

(54) Motor Controller Control Method, Apparatus, Device, and Storage Medium

(71) Applicant: EHANG INTELLIGENT EQUIPMENT (GUANGZHOU) CO., LTD., Guangzhou, Guangdong (CN)

(72) Inventors: Huazhi Hu, Guangzhou, Guangdong (CN); Tengfei Chen, Guangzhou, Guangdong (CN); Huipemg Xie, Guangzhou, Guangdong (CN); Yinchu Peng, Guangzhou, Guangdong (CN)

(21) Appl. No.: 19/130,588

(22) PCT Filed: Nov. 14, 2023
(86) PCT No.: PCT/CN2023/131515

§ 371 Date: May 16, 2025

(30) Foreign Application Priority Data
Nov. 17, 2022 (CN) 202211439057.2

(51) Int. Cl. H02P 23/00; B64U 50/19; G11C 16/20; G11C 16/26

(52) U.S. Cl. CPC H02P 23/0077; B64U 50/19; G11C 16/20; G11C 16/26

(57) ABSTRACT

A motor controller control method, apparatus, device, and storage medium is disclosed. The method includes: initializing hardware; reading parameter settings, enabling motor control interrupts, and configuring the task list; entering the main task loop of the motor controller and sending status data to the flight control system in real time; controlling the motor controller through the task control logic of the motor controller and sending status data to the flight control system and the host computer in real time.

### TECHNICAL FIELD

This application belongs to the field of drone technology, and in particular, relates to a motor controller control method, apparatus, device, and storage medium.

### BACKGROUND ART

With the continuous development of unmanned aerial vehicles, safely operating these vehicles has become a critical issue. During flight of the aerial vehicles, the flight control system sends real-time propeller speed control commands to each power unit based on the aircraft's attitude and flight speed control requirements. The motor controller calculates the three-phase current and voltage required for motor operation based on the rotation speed requirements. Through the power main circuit of the motor controller, the DC power supply is inverted into the three-phase AC power required for motor rotation. At this point, to enable the aerial vehicle to adjust its flight attitude promptly, higher requirements are imposed on the control logic of the motor controller to avoid impacting user experience.

### SUMMARY OF THE INVENTION

### Technical Issue

This application aims to provide a motor controller control method, apparatus, device, and storage medium to address the technical problem of improving the real-time performance and stability of the motor control system when controlling the motor controller through its task control logic.

Technical Solution

The technical solutions adopted by this application to solve the above technical problem are as follows:
According to one aspect of this application, a motor controller control method is provided, including:
initializing a hardware;
reading a parameter setting, enabling a motor control interrupt, and configuring a task list;
entering a main task loop of the motor controller and sending a status data to a flight control system in real time.

Optionally, reading the parameter setting, enabling the motor control interrupt, and configuring the task list includes:
reading an EEPROM parameter setting and verifying an EEPROM parameter;
upon successful verification, enabling the motor control interrupt, and configuring the task list;
upon failed verification, resetting the EEPROM parameter through a user task loop entry and restarting the controller.

According to another aspect of this disclosure, a motor controller control apparatus is provided, including:
an initialization module configured to initialize a hardware;
a reading module configured to read a parameter setting, enable a motor control interrupt, and configure a task list;
a control module configured to enter a main task loop of the motor controller and send a status data to a flight control system in real time.

According to yet another aspect of this disclosure, a motor controller control device is provided, including: a memory, a processor, and a computer program stored in the memory and executable on the processor, wherein the computer program, when executed by the processor, implements steps of the above motor controller control method.

According to still another aspect of this disclosure, a storage medium having stored thereon a program for a motor controller control method is provided, the program, when executed by a processor, implements steps of the above motor controller control method.

### Beneficial Effect

The embodiments of the present disclosure provide a motor controller control method, apparatus, device, and storage medium. The method involves initializing hardware; reading parameter settings, enabling motor control interrupts, and configuring a task list; entering the main task loop of the motor controller and sending status data to the flight control system in real time. This enables control of the motor controller through its task control logic, while sending status data to the flight control system and the host computer in real time, thereby improving the real-time performance and stability of the motor control system.

### DESCRIPTION OF THE DRAWINGS

FIG. 1 is a flowchart of a motor controller control method provided in Embodiment 1 of the present disclosure;

FIG. 2 is a structural diagram of a software framework for a motor controller provided in Embodiment 1 of the present disclosure;

FIG. 3 is a flowchart of the method for step S20 in FIG. 1;

FIG. 4 is a flowchart of the method for step S30 in FIG. 1;

FIG. 5 is a flowchart of the method for step S35 in FIG. 4;

FIG. 6 is an exemplary structural block diagram of a motor controller control apparatus provided in Embodiment 2 of the present disclosure;

FIG. 7 is an exemplary structural block diagram of the reading module in FIG. 6;

FIG. 8 is an exemplary structural block diagram of the control module in FIG. 6; and

FIG. 9 is an exemplary structural block diagram of a motor controller control device provided in Embodiment 3 of the present disclosure.

The realization, functional features, and advantages of the objectives of this application will be further described in conjunction with the embodiments and with reference to the accompanying drawings.

### DETAILED DESCRIPTION OF INVENTION

To make the technical problems, technical solutions, and beneficial effects of this application clearer and more understandable, the application is further described in detail below in conjunction with the accompanying drawings and embodiments. It should be understood that the specific embodiments described herein are merely for explaining the application and are not intended to limit the application.

In the following description, suffixes such as “module,” “component,” or “unit” used to denote elements are employed solely for the convenience of describing the present disclosure and have no specific meaning in themselves. Therefore, “module,” “component,” or “unit” may be used interchangeably.

### Embodiment 1

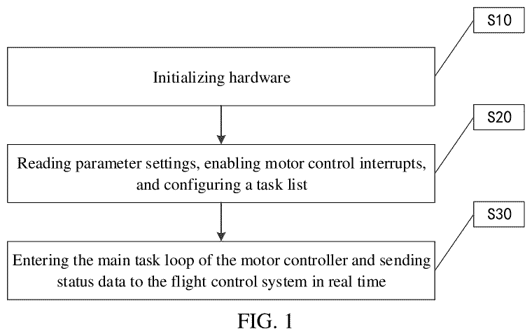

As shown in FIG. 1, in this embodiment, a motor controller control method includes:
S10: Initializing hardware.
S20: Reading parameter settings, enabling motor control interrupts, and configuring a task list.
S30: Entering the main task loop of the motor controller and sending status data to the flight control system in real time.

In this embodiment, the motor controller is controlled through its task control logic, and status data is sent to the flight control system and the host computer in real time, thereby improving the real-time performance and stability of the motor control system and enhancing user experience.

In this embodiment, based on the composition and principles of the motor controller circuit, the motor controller software is responsible for controlling various hardware circuits, collecting and processing sensor output signals, and receiving control commands from the flight control system. Through motor control algorithms, the software calculates and processes information such as voltage, current, and temperature of the motor operation, outputs control signals for power devices to regulate motor rotation speed and torque, and feeds back the operational status of the motor and controller to the flight control system.

In this embodiment, the motor control software runs on a microprocessor chip in the control circuit, specifically the TI TMS320F28069F digital signal control chip. The development environment (IDE) for the control software is TI's Code Composer Studio 9, with the primary programming language being standard C. The configuration of the chip's peripheral drivers utilizes TI C2000 assembly functions.

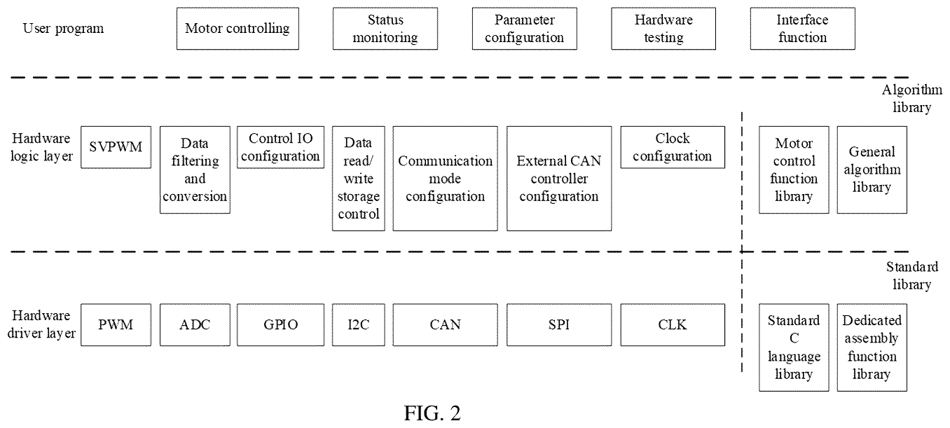

In this embodiment, the software framework of the motor controller, as shown in FIG. 2, is divided into three layers. The user layer primarily handles motor control logic and calculations, information interaction with the flight control system and host computer, as well as specialized functions such as operational status monitoring, firmware upgrades, and parameter configuration. The hardware control layer and algorithm library form the second layer, including general-purpose function libraries. The hardware control layer serves as an abstraction layer for specific hardware circuits, implementing logical control and data transmission/reception for these circuits, and providing the user layer functions with universal hardware control interfaces and data, such as SVPWM control logic, sampled data filtering and conversion, and communication protocol configuration. The algorithm library mainly includes motor control function libraries and general algorithm libraries, offering reusable mathematical operations and data processing function modules. The third layer primarily includes the hardware driver layer and library functions of the programming languages used. The hardware driver layer functions mainly handle the configuration and control of peripheral circuit modules of the adopted processor chip, such as PWM circuits, IO ports, ADC circuits, and CAN interface circuits, providing callable interfaces and data for the hardware control layer functions. The C language function library and assembly language function library provide commonly used function call capabilities for program development.

As shown in FIG. 3, in this embodiment, the step S20 includes:
S21: Reading EEPROM parameter settings.

S22: Verifying the EEPROM parameters.
S23: Upon successful verification, enabling motor control interrupts and configuring the task list.
S24: Upon failed verification, resetting the EEPROM parameters through the user task loop entry, restarting the controller, and returning to step S10.

In this embodiment, the parameter settings also include CAN bus parameter settings.

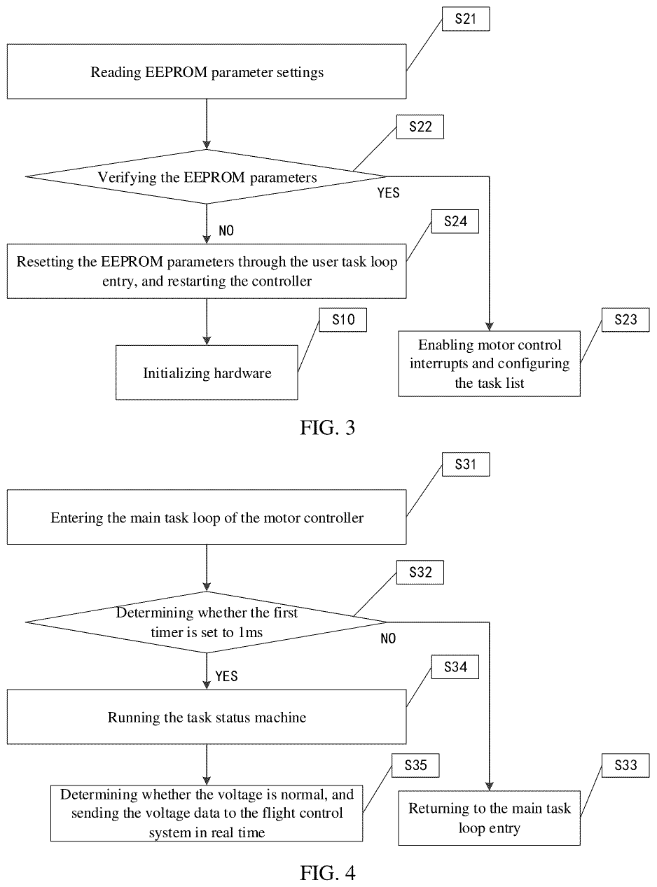

As shown in FIG. 4, in this embodiment, the step S30 includes:
S31: Entering the main task loop of the motor controller.
S32: Determining whether the first timer is set to 1 ms; if not, S33: returning to the main task loop entry.
If yes, S34: running the task status machine, S35: determining whether the voltage is normal, and sending the voltage data to the flight control system in real time.

In this embodiment, before running the task status machine, the method further includes:
turning on the LED operation indicator light.

As another embodiment, the task status machine may also monitor information such as current and temperature.

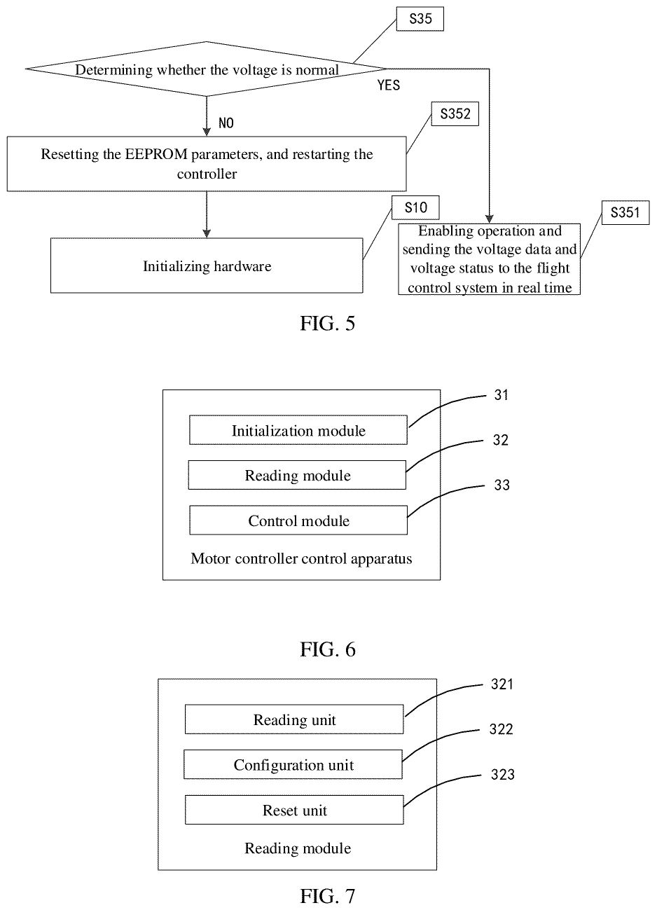

As shown in FIG. 5, in this embodiment, the step S35 includes:
If the voltage is normal, S351: enabling operation and sending the voltage data and voltage status to the flight control system in real time.
If the voltage is abnormal, S352: resetting the EEPROM parameters, restarting the controller, and returning to step S10.

In this embodiment, the initialization of hardware includes:
Initializing hardware circuits, the hardware circuits including a PWM circuit, IO ports, an ADC circuit, and a CAN interface circuit.

### Embodiment 2

As shown in FIG. 6, in this embodiment, a motor controller control apparatus 30 includes:
An initialization module 31 configured to initialize hardware.
A reading module 32 configured to read parameter settings, enable motor control interrupts, and configure a task list.
A control module 33 configured to enter the main task loop of the motor controller and send status data to the flight control system in real time.

In this embodiment, the motor controller is controlled through its task control logic, and status data is sent to the flight control system and the host computer in real time, thereby improving the real-time performance and stability of the motor control system and enhancing user experience.

In this embodiment, based on the composition and principles of the motor controller circuit, the motor controller software is responsible for controlling various hardware circuits, collecting and processing sensor output signals, and receiving control commands from the flight control system. Through motor control algorithms, the software calculates and processes information such as voltage, current, and temperature of the motor operation, outputs control signals for power devices to regulate motor rotation speed and torque, and feeds back the operational status of the motor and controller to the flight control system.

In this embodiment, the motor control software runs on a microprocessor chip in the control circuit, specifically the TI TMS320F28069F digital signal control chip. The development environment (IDE) for the control software is TI's Code Composer Studio 9, with the primary programming language being standard C. The configuration of the chip's peripheral drivers utilizes TI C2000 assembly functions.

In this embodiment, the software framework of the motor controller, as shown in FIG. 2, is divided into three layers. The user layer primarily handles motor control logic and calculations, information interaction with the flight control system and host computer, as well as specialized functions such as operational status monitoring, firmware upgrades, and parameter configuration. The hardware control layer and algorithm library form the second layer, including general-purpose function libraries. The hardware control layer serves as an abstraction layer for specific hardware circuits, implementing logical control and data transmission/reception for these circuits, and providing the user layer functions with universal hardware control interfaces and data, such as SVPWM control logic, sampled data filtering and conversion, and communication protocol configuration. The algorithm library mainly includes motor control function libraries and general algorithm libraries, offering reusable mathematical operations and data processing function modules. The third layer primarily includes the hardware driver layer and library functions of the programming languages used. The hardware driver layer functions mainly handle the configuration and control of peripheral circuit modules of the adopted processor chip, such as PWM circuits, IO ports, ADC circuits, and CAN interface circuits, providing callable interfaces and data for the hardware control layer functions. The C language function library and assembly language function library provide commonly used function call capabilities for program development.

As shown in FIG. 7, in this embodiment, the reading module includes:
A reading unit 321 configured to read EEPROM parameter settings and verify the EEPROM parameters.
A configuration unit 322 configured to, upon successful verification, enable motor control interrupts and configure the task list.
A reset unit 323 configured to, upon failed verification, reset the EEPROM parameters through the user task loop entry and restart the controller.

In this embodiment, the parameter settings also include CAN bus parameter settings.

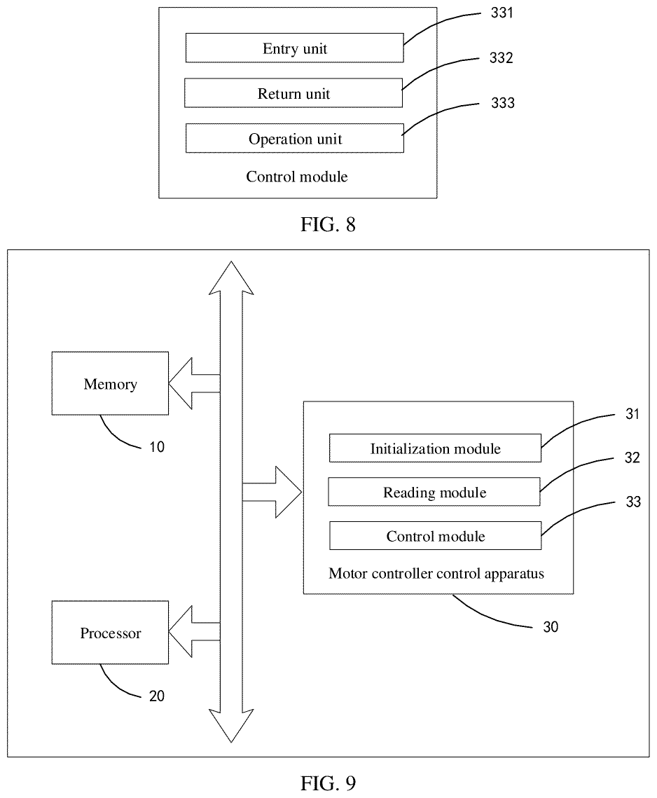

As shown in FIG. 8, in this embodiment, the control module includes:
An entry unit 331 configured to enter the main task loop of the motor controller.
A return unit 332 configured to determine whether the first timer is set to 1 ms and, if not, return to the main task loop entry.
An operation unit 333 configured to, when the first timer is set to 1 ms, run the task status machine, determine whether the voltage is normal, and send the voltage data to the flight control system in real time.

In this embodiment, before running the task status machine, the method further includes:
turning on the LED operation indicator light.

As another embodiment, the task status machine may also monitor information such as current and temperature.

### Embodiment 3

As shown in FIG. 9, in this embodiment, a motor control device includes: a memory 10, a processor 20, and a computer program stored in the memory and executable on the processor, such as the motor controller control apparatus 30 described in Embodiment 2. When the motor controller control apparatus is executed by the processor, it implements the steps of the motor controller control method as described above.

In this embodiment, the motor controller is controlled through its task control logic, and status data is sent to the flight control system and the host computer in real time, thereby improving the real-time performance and stability of the motor control system.

In this embodiment, the memory includes at least one type of readable storage medium used to store the operating system and various application software installed on the electronic device, such as the program code for the motor controller control method. Additionally, the memory may also be used to temporarily store various types of data that have been output or are to be output.

In this embodiment, the processor, in some embodiments, may be a Central Processing Unit (CPU), controller, microcontroller, microprocessor, or other data processing chip. The processor is typically used to control the overall operation of the electronic device. In this embodiment, the processor is used to run program code or process data stored in the memory, such as executing the motor controller control method.

### Embodiment 4

In this embodiment, a storage medium is provided, having stored thereon a program for a motor controller control method. When the program for the motor controller control method is executed by a processor, it implements the steps of the motor controller control method as described above.

The computer-readable storage medium provided by the embodiments of the present disclosure controls the motor controller through its task control logic and sends status data to the flight control system and the host computer in real time, thereby improving the real-time performance and stability of the motor control system.

Through the description of the above embodiments, those skilled in the art can clearly understand that the methods of the above embodiments can be implemented by means of software combined with a necessary general-purpose hardware platform, or, of course, by hardware alone, although in many cases the former is the preferred implementation. Based on this understanding, the technical solution of the present disclosure, or the part thereof that contributes to the prior art, can essentially be embodied in the form of a software product. This computer software product is stored in a storage medium (such as ROM/RAM, magnetic disk, or optical disk) and includes several instructions to enable a terminal device (which may be a mobile phone, computer, server, air conditioner, or network device, etc.) to execute the methods of the various embodiments of the present disclosure.

The preferred embodiments of the present disclosure have been described above with reference to the accompanying drawings, but these do not limit the scope of the invention. Any modifications, equivalent substitutions, and improvements made by those skilled in the art without departing from the scope and essence of the present disclosure shall fall within the scope of the invention's claims.

### INDUSTRIAL APPLICABILITY

The motor controller control method, apparatus, device, and storage medium proposed by the present disclosure involve initializing hardware; reading parameter settings, enabling motor control interrupts, and configuring a task list; entering the main task loop of the motor controller and sending status data to the flight control system in real time. This enables control of the motor controller through its task control logic and real-time transmission of status data to the flight control system and the host computer, thereby improving the real-time performance and stability of the motor control system. Therefore, it has industrial applicability.

1. A motor controller control method, comprising:
initializing a hardware;
reading a parameter setting, enabling a motor control interrupt, and configuring a task list; and
entering a main task loop of the motor controller and sending a status data to a flight control system in real time.

2. The motor controller control method according to claim 1, wherein reading the parameter setting, enabling the motor control interrupt, and configuring the task list comprises:
reading an EEPROM parameter setting and verifying an EEPROM parameter;
upon successful verification, enabling the motor control interrupt, and configuring the task list; and
upon failed verification, resetting the EEPROM parameter through a user task loop entry and restarting the controller.

3. The motor controller control method according to claim 1, wherein entering the main task loop of the motor controller and sending the status data to the flight control system in real time comprises:
entering the main task loop of the motor controller;
determining whether a first timer is set to 1 ms; in response to that the first timer is not set to 1 ms, returning to an entry of the main task loop; and
in response to that the first timer is set to 1 ms, running a task status machine, determining whether a voltage is normal, and sending a voltage data to the flight control system in real time.

4. The motor controller control method according to claim 3, wherein determining whether the voltage is normal and sending the voltage data to the flight control system in real time comprises:
in response to that the voltage is normal, enabling an operation and sending the voltage data and a voltage status to the flight control system in real time;
in response to that the voltage is abnormal, resetting an EEPROM parameter and restarting the controller.

5. The motor controller control method according to claim 1, wherein initializing the hardware comprises:
initializing a hardware circuit, the hardware circuit comprising a PWM circuit, an IO port, an ADC circuit, and a CAN interface circuit.

6. A motor controller control apparatus, comprising:
an initialization module configured to initialize a hardware;
a reading module configured to read a parameter setting, enable a motor control interrupt, and configure a task list;
a control module configured to enter a main task loop of the motor controller and send a status data to a flight control system in real time.

7. The motor controller control apparatus according to claim 6, wherein the reading module comprises:
a reading unit configured to read an EEPROM parameter setting and verify an EEPROM parameter;
a configuration unit configured to, upon successful verification, enable the motor control interrupt, and configure the task list;
a reset unit configured to, upon failed verification, reset the EEPROM parameter through a user task loop entry and restart the controller.

8. The motor controller control apparatus according to claim 6, wherein the control module comprises:
an entry unit configured to enter the main task loop of the motor controller;
a return unit configured to determine whether a first timer is set to 1 ms; in response to that the first timer is not set to 1 ms, return to an entry of the main task loop;
an operation unit configured to, in response to that the first timer is set to 1 ms, run a task status machine, determine whether the voltage is normal, and send a voltage data to the flight control system in real time.

9. A motor controller control device, comprising: a memory, a processor, and a computer program stored in the memory and executable on the processor, wherein the computer program, when executed by the processor, implements steps of the motor controller control method according to claim 1.

10. A storage medium having stored thereon a program for a motor controller control method, wherein the program, when executed by a processor, implements steps of the motor controller control method according to claim 1.

11. A motor controller control device, comprising: a memory, a processor, and a computer program stored in the memory and executable on the processor, wherein the computer program, when executed by the processor, implements steps of the motor controller control method according to claim 2.

12. A motor controller control device, comprising: a memory, a processor, and a computer program stored in the memory and executable on the processor, wherein the computer program, when executed by the processor, implements steps of the motor controller control method according to claim 3.

13. A motor controller control device, comprising: a memory, a processor, and a computer program stored in the memory and executable on the processor, wherein the computer program, when executed by the processor, implements steps of the motor controller control method according to claim 4.

14. A motor controller control device, comprising: a memory, a processor, and a computer program stored in the memory and executable on the processor, wherein the computer program, when executed by the processor, implements steps of the motor controller control method according to claim 5.

15. A storage medium having stored thereon a program for a motor controller control method, wherein the program, when executed by a processor, implements steps of the motor controller control method according to claim 2.

16. A storage medium having stored thereon a program for a motor controller control method, wherein the program, when executed by a processor, implements steps of the motor controller control method according to claim 3.

17. A storage medium having stored thereon a program for a motor controller control method, wherein the program, when executed by a processor, implements steps of the motor controller control method according to claim 4.

18. A storage medium having stored thereon a program for a motor controller control method, wherein the program, when executed by a processor, implements steps of the motor controller control method according to claim 5.
